(19) United States
(12) Patent Application Publication
(10) Pub. No.: US 2015/0027376 A1
(43) Pub. Date: Jan. 29, 2015

(54) DEPOSITION FILM FORMING APPARATUS INCLUDING ROTATING MEMBERS

(71) Applicant: TGO Tech. Corporation, Hwaseong-si (KR)

(72) Inventors: Chung Seok OH, Hwaseong-si (KR); Yoo Jin LEE, Yongin-si (KR); Jae Hak LEE, Seoul (KR)

(21) Appl. No.: 14/336,093

(22) Filed: Jul. 21, 2014

(30) Foreign Application Priority Data
Jul. 26, 2013 (KR) 10-2013-0088754

(51) Int. Cl. C23C 16/458

(52) U.S. Cl. CPC C23C 16/4584; C23C 16/4409
USPC 118/730

(57) ABSTRACT

A deposition film forming apparatus including rotary members includes a plurality of substrate supports, wherein a plurality of substrates are disposed on each of the substrate supports, and each of the substrates is rotated on the substrate supports by means of a gas-foil method.

### FIELD OF THE INVENTION

The present invention relates to a deposition film forming apparatus including rotary members. In particular, the present invention relates to a deposition film forming apparatus in which rotation of substrates may be controlled by rotary members included in each of a plurality of substrate supports.

### BACKGROUND

A light emitting diode (LED) is a semiconductor light-emitting device for converting electric current to light, which has been widely used as a light source for displaying images in an electronic apparatus including data communication equipment. In particular, as it is known that unlike conventional lighting such as incandescent or fluorescent lamps, LEDs have high efficiency of converting electric energy into light energy and thus can save energy up to 90%, LEDs are drawing extensive attention as devices which can replace fluorescent or incandescent lamps.

A process of manufacturing an LED device may be generally divided into an epitaxial process, a chip process, and a package process. The epitaxial process refers to a process of epitaxially growing a compound semiconductor on a substrate. The chip process refers to a process of forming an electrode in each portion of the epitaxially grown substrate to fabricate an epitaxial chip. The package process refers to a process of connecting a lead to the epitaxial chip fabricated as above and packaging the epitaxial chip such that light can be emitted outwardly as much as possible.

Among the above processes, it may be considered that the epitaxial process is the most essential process which decides light emitting efficiency of the LED device. This is because when the compound semiconductor is not epitaxially grown on the substrate, a defect may occur within a crystal and act as a non-radiative center, thereby deteriorating the light emitting efficiency of the LED device.

For the epitaxial process, i.e., the process of forming an epitaxial layer on a substrate, a liquid phase epitaxy (LPE) method, vapor phase epitaxy (VPE) method, molecular beam epitaxy (MBE) method, chemical vapor deposition (CVD) method, or the like is employed. Among others, a metal-organic chemical vapor deposition (MOCVD) method or hydride vapor phase epitaxy (HYPE) method is mainly employed.

When an epitaxial layer is formed on a plurality of substrates using a conventional MOCVD method or HVPE method, a process gas for processing the substrates within a chamber is typically supplied. In order to improve process uniformity, it is preferable that a substrate support on which the plurality of substrates are seated is revolved. Further, it is also preferable that each of the plurality of substrates is rotated on the substrate support. However, it has been difficult to configure a conventional deposition film forming apparatus such that the substrate support is revolved while each of the plurality of substrates is rotated.

### SUMMARY OF THE INVENTION

The present invention has been contrived to solve all the above-mentioned problems of prior art, and one object of the invention is to provide a deposition film forming apparatus in which rotation of substrates may be controlled by rotary members included in each of a plurality of substrate supports.

According to one embodiment of the invention, there is provided a deposition film forming apparatus comprising a plurality of substrate supports, wherein a plurality of substrates are disposed on each of the substrate supports and each of the substrates is rotated on the substrate supports by means of a gas-foil method.

According to the invention, there is provided a deposition film forming apparatus in which rotation of substrates may be controlled by rotary members included in each of a plurality of substrate supports.

In addition, according to the invention, there is provided a deposition film forming apparatus which may improve uniformity of a deposition film between a plurality of substrates.

### BRIEF DESCRIPTION OF THE DRAWINGS

FIG. 1 shows the configuration of a deposition film forming apparatus according to one embodiment of the invention.

FIG. 2 shows the configuration of a substrate support according to one embodiment of the invention.

FIG. 3 shows the configuration of a part of the substrate support according to one embodiment of the invention.

FIG. 4 shows the configuration of a part of the deposition film forming apparatus according to one embodiment of the invention.

FIG. 5 is an enlarged view of portion B of FIG. 4.

FIG. 6 shows the configuration of a first support according to one embodiment of the invention.

### DETAILED DESCRIPTION OF THE PREFERRED EMBODIMENTS

In the following detailed description of the present invention, references are made to the accompanying drawings that show, by way of illustration, specific embodiments in which the invention may be practiced. These embodiments are described in sufficient detail to enable those skilled in the art to carry out the invention. It should be understood that the various embodiments of the invention, although different from each other, are not necessarily mutually exclusive. For example, specific shapes, structures, and characteristics described herein may be implemented as modified from one embodiment to another without departing from the spirit and scope of the invention. Moreover, it should be understood that the locations or arrangements of individual elements within each of the embodiments described herein may also be modified without departing from the spirit and scope of the invention. Accordingly, the following detailed description is not to be taken in a limiting sense, and the scope of the invention is to be limited only by the scope of the appended claims and all equivalents thereof, as long as properly described. In the drawings, like reference numerals refer to the same or similar functions throughout the several views.

Hereinafter, the configuration of the present invention will be described in detail with reference to the accompanying drawings.

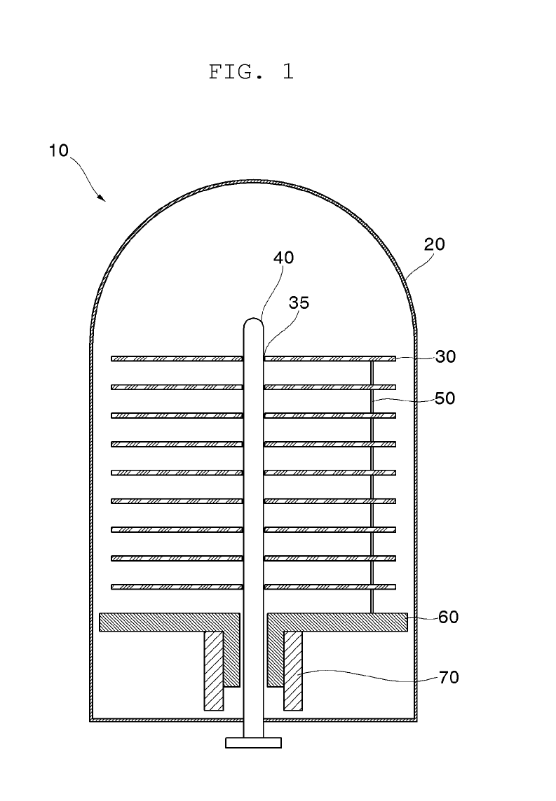

FIG. 1 shows the configuration of a deposition film forming apparatus according to one embodiment of the invention;

First, the material of a substrate (not shown) loaded in a deposition film forming apparatus 10 is not particularly limited, and the substrate made of various materials, such as glass, plastic, polymer, silicon wafer, stainless steel, and sapphire, may be loaded. Hereinafter, it will be assumed that the substrate is a circular sapphire substrate employed in the field of light emitting diodes.

The deposition film forming apparatus 10 according to one embodiment of the invention may comprise a chamber 20. The chamber 20 is configured such that the internal space thereof is substantially sealed while a process is performed, and may function to provide a space in which a deposition film is formed on a plurality of substrates. The chamber 20 is configured to maintain an optimum process condition, and may be formed in a rectangular or circular shape. The material of the chamber 20 is preferably a quartz glass, but is not limited thereto.

In general, a process for forming a deposition film on a substrate is performed by supplying a deposition material into the chamber 20 and heating the inside of the chamber to a predetermined temperature (e.g., about 800° C. to 1,200° C.). The supplied deposition material is supplied to the substrate to be involved in the formation of the deposition film.

The deposition film forming apparatus 10 according to one embodiment of the invention may comprise a heater (not shown). The heater may be installed outside the chamber 20 and function to apply heat required for a deposition process to a plurality of substrates. In order to facilitate the growth of the deposition film on the substrates, the heater may heat the substrates to a temperature of about 1,200° C. or higher.

The deposition film forming apparatus 10 according to one embodiment of the invention may comprise a substrate support 30. It is preferable that the substrate support 30 is provided in plural, and they are arranged and installed in tiers. When the substrate support 30 is provided in plural, the plurality of substrate supports 30 may be arranged and fixed to have a predetermined interval from each other by means of spacing members (not shown). The number of the substrate supports 30 may be variously changed according to the purpose for which the present invention is intended. The substrate supports 30 and the spacing members are preferably made of a quartz glass, but are not limited thereto.

A central through-hole 35 may be formed at the center of the substrate supports 30 such that a process gas supply unit 40 to be described later may pass through the center of the substrate supports 30. It is preferable that the diameter of the central through-hole 35 is somewhat larger than that of the process gas supply unit 40.

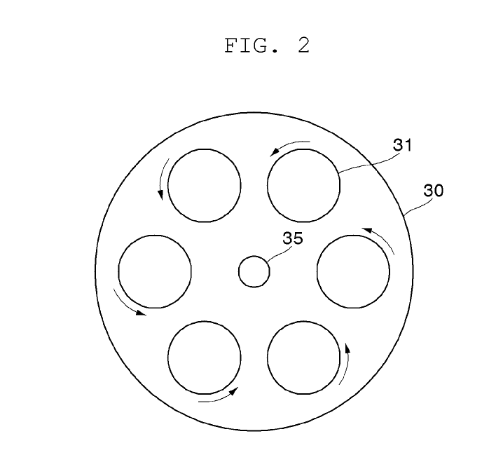

In addition, a plurality of rotary members 31 (see FIG. 2) may be installed on the substrate support 30. The number of the rotary members 31 installed on each substrate support 30 is preferably the same as that of the substrates disposed on each substrate support 30, but is not necessarily limited thereto. In order to ensure that a substrate processing gas is uniformly supplied to the substrates, the rotary members 31 may function to enable rotation of the substrates. A detailed configuration thereof will be described later.

The deposition film forming apparatus 10 according to one embodiment of the invention may comprise a process gas supply unit 40. The process gas supply unit 40 may function to supply a substrate processing gas required for the formation of the deposition film into the chamber 20.

Herein, the process gas supply unit 40 is described as being disposed to pass through the central through-hole 35 at the center of the substrate supports 30, but is not limited thereto.

The deposition film forming apparatus 10 according to one embodiment of the invention may comprise a first support 60. The first support 60 may be installed at the lower part of the chamber 20 to support the plurality of substrate supports 30 while the deposition process is performed. In addition, the first support 60 may be rotated by a separate rotating apparatus (not shown), thereby functioning to cause revolution of the plurality of substrate supports 30.

The deposition film forming apparatus 10 according to one embodiment of the invention may comprise a second support 70. The second support 70 may be installed at the lower part of the chamber 20 together with the first support 60, and configured to surround the outer periphery of the first support 60. In addition, the second support 70 may be installed to be fixed with respect to the chamber 20 despite the rotation of the first support 60.

Hereinafter, the configuration of the substrate support 30 according to one embodiment of the invention will be described in more detail.

FIG. 2 shows the configuration of the substrate support 30 according to one embodiment of the invention.

Referring to FIG. 2, the substrate support 30 according to one embodiment of the invention may comprise a plurality of rotary members 31 on which a plurality of substrates may be seated. The rotary member 31 may have a shape corresponding to that of the substrate, e.g., a circular shape. Each of the plurality of rotary members 31 may be rotated on the substrate support 30 by means of a gas-foil method.

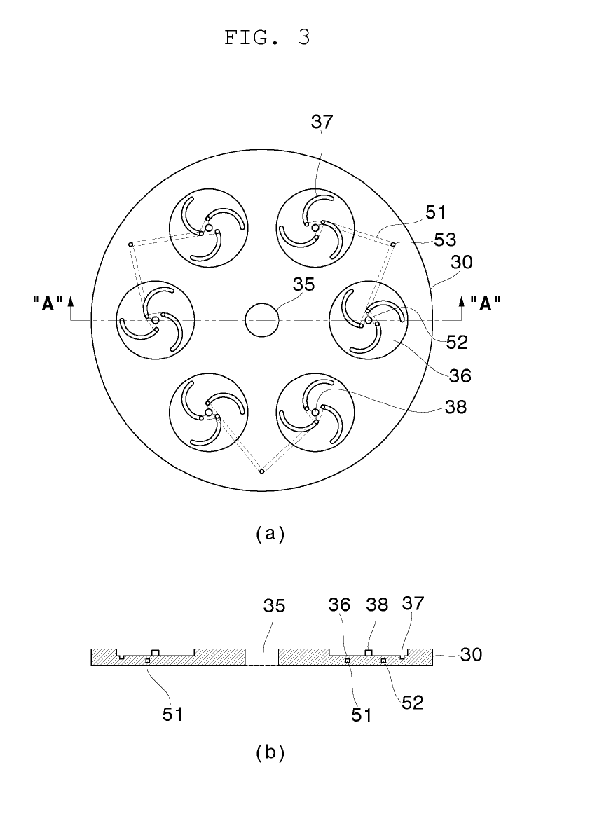

FIG. 3 shows the configuration of a part of the substrate support 30 according to one embodiment of the invention.

(a) of FIG. 3 illustrates a state in which the rotary members 31 are removed from the substrate support 30, and (b) of FIG. 3 is a cross-sectional view taken along line A-A in (a) of FIG. 3. Referring to (a) and (b) of FIG. 3, at the positions where the rotary members 31 are disposed on the substrate support 30, rotary member receiving portions 36 may be formed to provide spaces in which the rotary members 31 are seated. If the rotary members 31 are in the shape of a circular plate, the rotary member receiving portions 36 may be formed in a concave shape corresponding to the circular plate.

Grooves 37 may be formed on the rotary member receiving portions 36. A predetermined gas (e.g., N₂ gas) may flow in the grooves 37 and may be supplied through first flow channels 51 and second flow channels 52. The flow of the predetermined gas in the grooves 37 may provide a rotational force to rotate the rotary members 31. The grooves 37 may be formed in a shape to rotate the rotary members 31 in a predetermined direction, e.g., in a spiral shape having a predetermined direction. Although FIG. 3 illustrates that the second flow channels 52 are branched from the first flow channels 51, the present invention is not limited thereto and the shape and number of the flow channels may be changed as needed.

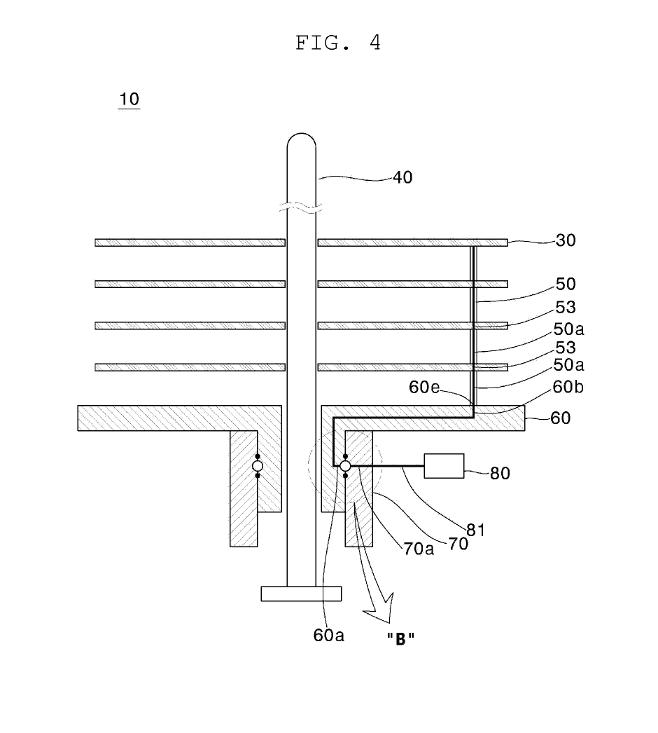

One end of the first flow channel 51 may be connected with a third flow channel 53, and a predetermined gas supplied from a gas supply unit 80 (see FIG. 4) to be described later may flow in the third flow channel 53. FIG. 3 illustrates that three third flow channels are formed in the substrate support 30, and two first flow channels 51 are branched from each of the third flow channels 53. However, the number of the third flow channels and the number of the first flow channels branched from the third flow channels are not limited thereto, and may be changed depending on the number and positions of the substrates seated on the substrate support 30.

A protrusion 38 may be formed at the center of the rotary member receiving portion 36 and may be engaged with a recess (not shown) formed at the center of the bottom surface of the rotary member 31. As the protrusion 38 is engaged with the recess of the rotary member 31 and a predetermined gas flows in the grooves 37, the rotary member 31 may be rotated about the protrusion 38.

Hereinafter, it will be described with reference to FIGS. 4 to 6 show a predetermined gas for rotating the rotary members 31 is supplied to the substrate support 30.

FIG. 4 shows the configuration of a part of the deposition film forming apparatus 10 according to one embodiment of the invention;

Referring to FIG. 4, the deposition film forming apparatus 10 according to one embodiment of the invention may comprise a gas supply unit 80. The gas supply unit 80 may supply a predetermined gas (e.g., N₂ gas) into the second support 70 through a gas supply path 81.

An internal supply path 70a may be formed within the second support 70 to provide a path in which a predetermined gas may flow. The predetermined gas flowing in the internal supply path 70a flows into a connection flow channel 50a formed within a connection tube 50, by way of an internal flow channel 60a within the first support 60 connected with the internal supply path 70a and through an outlet 60e abutting the connection tube 50. The connection flow channel 50a interconnects the plurality of substrate supports 30 so that the predetermined gas may be supplied to the uppermost substrate support 30. The third flow channels 53 are formed in each of the substrate supports 30 so that the predetermined gas may be supplied to the first flow channels 51 and the second flow channels 52.

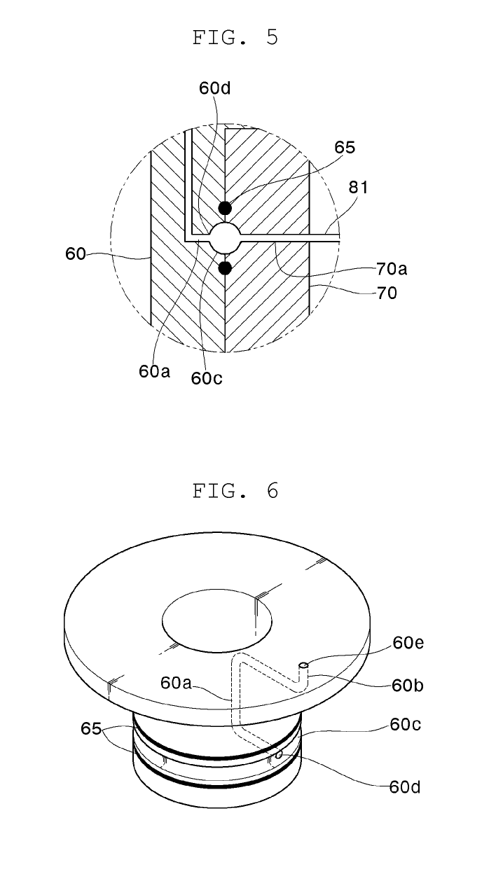

FIG. 5 is an enlarged view of portion B of FIG. 4. The portion B relates to a path through which a predetermined gas flows from the second support 70 to the first support 60. Further, FIG. 6 shows the configuration of the first support according to one embodiment of the invention.

Referring to FIGS. 5 and 6, a connection portion 60c may be formed on the first support 60 between the internal supply path 70a and the internal flow channel 60a. The connection portion 60c may be formed in the shape of a concave ring outside the first support 60 along the rotation direction of the first support 60. Therefore, even when the first support 60 is rotated, a predetermined gas supplied from the internal supply path 70a may flow into the internal flow channel 60a within the first support 60.

An inlet 60d from which the internal flow channel 60a extends may be formed at a predetermined position in the connection portion 60c. Since the first support 60 is rotatable, the position of the inlet 60d may also be rotated. Accordingly, even if the positions of the internal supply path 70a and the inlet 60d do not match each other, a predetermined gas discharged from the internal flow channel 60a may flow along the connection portion 60c having the concave ring shape and then flow into the inlet 60d. Sealing members 65 may be disposed along the upper and lower parts of the connection portion 60c to prevent the predetermined gas from leaking outwardly between the first support 60 and the second support 70.

Although the present invention has been illustrated and described above in connection with the preferred embodiments, the invention is not limited to the above embodiments, and various modifications and changes may be made by those skilled in the art to which the invention pertains without departing from the spirit of the invention. Such modifications and changes shall be taken as falling within the scope of the present invention and the appended claims.

What is claimed is:

1. A deposition film forming apparatus comprising:
a plurality of substrate supports,
wherein a plurality of substrates are disposed on each of the substrate supports, and each of the substrates is rotated on the substrate supports by means of a gas-foil method.

2. The deposition film forming apparatus of claim 1, wherein each of the plurality of substrate supports is rotatable.

3. The deposition film forming apparatus of claim 2, further comprising:
first and second supports for supporting the plurality of substrate supports,
wherein the first support is rotatable together with the plurality of substrate supports, and the second support is fixed.

4. The deposition film forming apparatus of claim 3, wherein an internal supply path is formed in the second support to convey a predetermined gas that allows the substrates to be rotated on the substrate supports;
an internal flow channel is formed in the first support to convey the predetermined gas to the plurality of substrate supports; and
a connection portion in the shape of a concave ring is formed on a lateral surface of the first support to interconnect the internal supply path and the internal flow channel.

5. The deposition film forming apparatus of claim 4, wherein a sealing member is formed in at least one of upper and lower parts of the connection portion to prevent leakage of the predetermined gas.

6. The deposition film forming apparatus of claim 2, wherein a plurality of rotary members corresponding to the plurality of substrates are formed on each of the substrate supports; and
each of the plurality of rotary members is rotated in the substrate supports.

7. The deposition film forming apparatus of claim 6, wherein a plurality of rotary member receiving portions in which each of the plurality of rotary members is seated are formed in the substrate supports; and
a groove is formed on a top surface of each of the plurality of rotary member receiving portions to allow the rotary members to be rotated.

8. The deposition film forming apparatus of claim 7, wherein the groove is in the shape of a spiral.

9. The deposition film forming apparatus of claim 7, wherein a flow channel is formed in each of the substrate supports to supply a predetermined gas to the groove.

10. The deposition film forming apparatus of claim 7, wherein a protrusion is formed on the top surface of each of the plurality of rotary member receiving portions, and each of the plurality of rotary members is rotatable about the protrusion.
